(19) United States
(12) Patent Application Publication
(10) Pub. No.: US 2022/0102432 A1
(43) Pub. Date: Mar. 31, 2022

(54) DISPLAY SUBSTRATE, MANUFACTURING METHOD THEREOF, AND DISPLAY PANEL

(71) Applicant: BOE TECHNOLOGY GROUP CO., LTD., Beijing (CN)

(72) Inventors: Dini Xie, Beijing (CN); Wei Li, Beijing (CN)

(21) Appl. No.: 17/275,688

(22) PCT Filed: May 25, 2020
(86) PCT No.: PCT/CN2020/092046

§ 371 Date: Mar. 12, 2021

(30) Foreign Application Priority Data
May 30, 2019 (CN) 201910461033.9

(51) Int. Cl. H01L 27/32; H01L 51/52; H01L 51/56

(52) U.S. Cl. CPC H01L 27/322; H01L 51/5268; H01L 2227/323; H01L 51/56; H01L 27/3244

(57) ABSTRACT

Provided is a display substrate, including: a base substrate and a color filter layer disposed on a side of the base substrate, wherein a target surface of the color filter layer is provided with a scattering structure, and the target surface comprises at least one of a first surface and a second surface opposite to each other.

This application claims priority to Chinese Patent Application No. 201910461033.9, filed on May 30, 2019 and entitled “DISPLAY SUBSTRATE, FABRICATION METHOD THEREOF, AND DISPLAY PANEL”, the disclosures of which are herein incorporated by reference in their entireties.

### TECHNICAL FIELD

The present disclosure relates to the field of display technologies, and in particular to a display substrate, a manufacturing method thereof, and a display panel.

### BACKGROUND

With the development of display technologies, the quality requirements for display panels are becoming higher and higher. The viewing angle of the display panel is an important index for measuring the quality of the display panel.

### SUMMARY

The present disclosure provides a display substrate, a manufacturing method thereof, and a display panel. The technical solution is as follows.

In a first aspect, a display substrate is provided. The display substrate includes:

a base substrate and a color filter layer disposed on a side of the base substrate, wherein a target surface of the color filter layer is provided with a scattering structure, and the target surface includes at least one of a first surface and a second surface opposite to each other.

Optionally, the scattering structure includes a plurality of grooves.

Optionally, the plurality of grooves include at least one of hemispherical grooves, inverted triangular pyramid grooves, and inverted prismatic table grooves.

Optionally, the plurality of grooves are uniformly arranged on the target surface.

Optionally, opening dimensions of the plurality of grooves are the same.

Optionally, aperture widths of the grooves range from 50 to 700 nanometers.

Optionally, the display substrate includes a first film layer attached to the target surface, wherein a material of the first film layer is different from a material of the color filter layer.

Optionally, the target surface includes the first surface proximal to the base substrate, the first film layer includes a passivation layer, and the display substrate includes a buffer layer and a thin-film transistor between the base substrate and the color filter layer, wherein the buffer layer, the thin-film transistor, and the passivation layer are sequentially arranged in a direction distal from the base substrate.

Optionally, the target surface includes the second surface distal from the base substrate, the first film layer includes a planarization layer, and the display substrate includes a buffer layer and a thin-film transistor between the base substrate and the color filter layer, wherein the buffer layer, the thin-film transistor, the passivation layer, the color filter layer and the planarization layer are sequentially arranged in a direction distal from the base substrate.

Optionally, the color filter layer is made of an organic material, the passivation layer is made of at least one of silicon oxide, silicon nitride, and aluminum oxide, and the planarization layer is made of photosensitive resin.

Optionally, shapes of the plurality of grooves are the same.

Optionally, the scattering structure includes a plurality of grooves;

the plurality of grooves include any of hemispherical grooves, inverted triangular pyramid grooves, or inverted prismatic table grooves, and opening dimensions of the plurality of grooves are the same;

the plurality of grooves are uniformly arranged on the target surface;

the display substrate includes a first film layer attached to the target surface, wherein a material of the first film layer is different from a material of the color filter layer; and

the target surface includes the first surface proximal to the base substrate, the first film layer includes a passivation layer, and the display substrate includes a buffer layer and a thin-film transistor between the base substrate and the color filter layer, wherein the buffer layer, the thin-film transistor and the passivation layer are sequentially arranged in a direction distal from the base substrate.

In a second aspect, a method for manufacturing a display substrate is provided. The method includes:

providing a base substrate;

forming a color filter layer on a side of the base substrate, wherein a target surface of the color filter layer is provided with a scattering structure, and the target surface includes at least one of a first surface and a second surface opposite to each other.

Optionally, after providing the base substrate, the method further includes:

sequentially forming a buffer layer, a thin-film transistor and a passivation layer on the base substrate; and

roughening a surface of the passivation layer; and

forming the color filter layer on a side of the base substrate includes:

forming the color filter layer on the passivation layer with the surface roughened, such that the scattering structure is formed on the first surface, proximal to the base substrate, of the color filter layer.

Optionally, after providing the base substrate, the method further includes:

sequentially forming a buffer layer, a thin-film transistor and a passivation layer on the base substrate; and

forming the color filter layer on one side of the base substrate includes:

forming the color filter layer on a side, distal from the base substrate, of the passivation layer; and

roughening a surface of the color filter layer, such that the scattering structure is formed on the second surface, distal from the base substrate, of the color filter layer.

Optionally, after forming the color filter layer on one side of the base substrate, the method further includes:

forming a planarization layer on a side, distal from the base substrate, of the color filter layer.

Optionally, the scattering structure includes a plurality of grooves.

Optionally, the plurality of grooves include at least one of hemispherical grooves, inverted triangular pyramid grooves, and inverted prismatic table grooves.

Optionally, the plurality of grooves are uniformly arranged on the target surface, and aperture widths of the grooves range from 50 to 700 nanometers.

In a third aspect, a display panel is provided. The display panel includes a display substrate of any of the above-mentioned aspects.

### BRIEF DESCRIPTION OF THE DRAWINGS

For clearer descriptions of the technical solutions in the embodiments of the present disclosure, the following briefly introduces the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a schematic structural diagram of a display substrate according to an embodiment of the present disclosure;

FIG. 2 is a schematic structural diagram of another display substrate according to an embodiment of the present disclosure;

FIG. 3 is a schematic structural diagram of yet another display substrate according to an embodiment of the present disclosure;

FIG. 4 is a schematic structural diagram of still another display substrate according to an embodiment of the present disclosure;

FIG. 5 is a schematic structural diagram of still another display substrate according to an embodiment of the present disclosure;

FIG. 6 is a flowchart of a method for manufacturing a display substrate according to an embodiment of the present disclosure;

FIG. 7 is a flowchart of another method for manufacturing a display substrate according to an embodiment of the present disclosure;

FIG. 8 is a partial structural diagram of a display substrate according to an embodiment of the present disclosure;

FIG. 9 is a flowchart of yet another method for manufacturing a display substrate according to an embodiment of the present disclosure;

FIG. 10 is a partial structural diagram of another display substrate according to an embodiment of the present disclosure; and

FIG. 11 is a schematic structural diagram of a display panel according to an embodiment of the present disclosure.

### DETAILED DESCRIPTION

Embodiments of the present disclosure are described below with reference to the accompanying drawings.

With the development of display technologies, display panels with larger viewing angles are becoming more and more popular. The following embodiments of the present disclosure provide a display substrate, which enables a display panel including the display substrate to have a larger viewing angle.

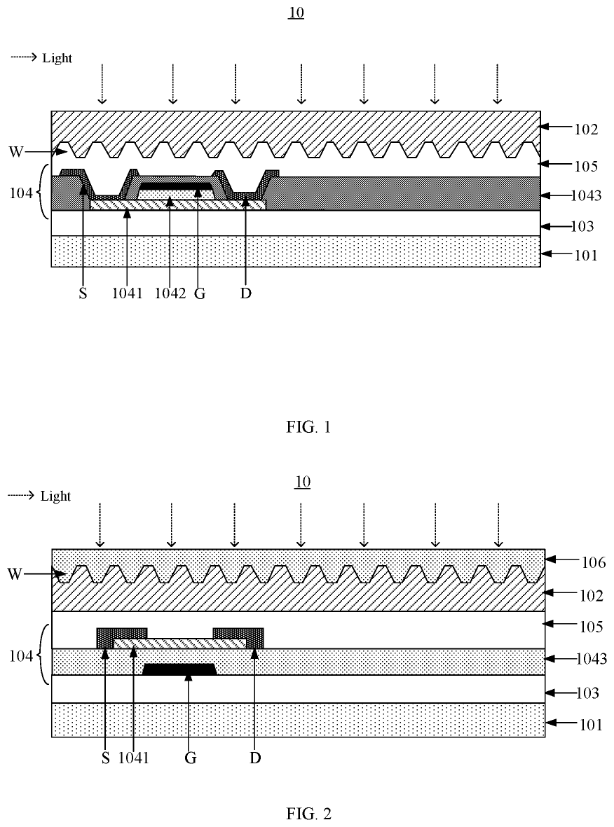

FIG. 1 is a schematic structural diagram of a display substrate according to an embodiment of the present disclosure. As shown in FIG. 1, the display substrate 10 includes a base substrate 101 and a color filter layer 102 located on a side of the base substrate 101. A target surface of the color filter layer 102 is provided with a scattering structure (not shown in FIG. 1). The target surface includes at least one of a first surface and a second surface opposite to each other.

The first surface is a surface, proximal to the base substrate 101, of the color filter layer 102. The second surface is a surface, distal from the base substrate 101, of the color filter layer 102. One of the first surface and the second surface is a light-incident surface, and the other is a light-emergent surface. The target surface includes at least one of the first surface and the second surface opposite to each other. That is, the target surface includes the first surface, or includes the second surface, or includes both the first surface and the second surface opposite to each other.

In an exemplary embodiment, in FIG. 1, the target surface of the color filter layer 102 only include the first surface. It should be noted that the arrow of light in FIG. 1 indicates an incident direction of light. That is, in FIG. 1, the first surface of the color filter layer 102 is a light-emergent surface, and the second surface is a light-incident surface. As shown in FIG. 1, the display substrate is a bottom emission structure. Optionally, the display substrate according to an embodiment of the present disclosure may also be a top emission structure, in which case the first surface of the color filter layer is a light-incident surface, and the second surface is a light-emergent surface. The following embodiments of the present disclosure are described by taking the display substrate being the bottom emission structure as an example.

In summary, according to the display substrate provided by the embodiment of the present disclosure, since the target surface of the color filter layer is provided with the scattering structure which plays a role in scattering light, the light can be scattered upon being exited from the scattering structure. In this way, the light-emergent angle of the display substrate is larger, which enables a display panel including the display substrate to have a larger viewing angle.

Optionally, the display substrate according to the embodiment of the present disclosure further includes a first film layer attached to the target surface of the color filter layer. A material of the first film layer may be different from a material of the color filter layer. If the target surface is the first surface of the color filter layer, the first film layer is a film layer that is in contact with the first surface of the color filter layer. If the target surface is the second surface of the color filter layer, the first film layer is a film layer that is in contact with the second surface of the color filter layer. If the target surface includes the first surface and the second surface of the color filter layer, the first film layer includes a film layer that is in contact with the first surface of the color filter layer and a film layer that is in contact with the second surface of the color filter layer.

Since the materials of the two laminated film layers are different, the light scattering effect at an interface of the two film layers is better. Consequently, the material of the first film layer attached to the target surface of the color filter layer being different from that of the color filter layer enables the scattering structure on the target surface of the color filter layer to have a better light scattering effect.

In an optional embodiment of the present disclosure, the above-mentioned display substrate is a self-luminous display substrate. For example, the display substrate is an organic light-emitting diode (OLED) display substrate or a quantum dot light-emitting diode (QLED) display substrate, etc. The embodiments of the present disclosure take the following three display substrates as examples to illustrate the scattering structure on the color filter layer.

The structure of a first display substrate is shown in FIG. 1. As shown in FIG. 1, the scattering structure of the color filter layer 102 is disposed on the first surface of the color filter layer 102. That is, the target surface of the color filter layer 102 includes the first surface. The display substrate 10 further includes a passivation layer 105 located between the base substrate 101 and the color filter layer 102. The passivation layer 105 is attached to the first surface of the color filter layer 102.

It should be noted that the first surface of the color filter layer 102 in FIG. 1 is a light-emergent surface of the color filter layer 102. That is, the scattering structure of the color filter layer 102 is disposed on the light-emergent surface of the color filter layer 102, and then the light can be scattered only after passing through the color filter layer 102, which prevents the light, after being scattered, from entering the color filter layer 102 and exiting from the area of the color filter layer 102 where light does not need to be emitted, thereby ensuring the precision of displaying images on the display substrate.

In the display substrate shown in FIG. 1, light directed to the color filter layer 102 may be white light and the white light becomes colored light after passing through the color filter layer 102. Further, after being scattered by the scattering structure on the first surface, with the scattering structure, of the color filter layer 102, the colored light is emitted from the color filter layer 102 and the base substrate 101 at a larger light-emergent angle, thereby realizing the color display of the display substrate 10.

The structure of a second display substrate is shown in FIG. 2. FIG. 2 is a schematic structural diagram of another display substrate according to an embodiment of the present disclosure. As shown in FIG. 2, the scattering structure of the color filter layer 102 is disposed on the second surface of the color filter layer 102. That is, the target surface of the color filter layer 102 includes the second surface. The display substrate 10 further includes a planarization layer 106 located on a side, distal from the base substrate 101, of the color filter layer 102. The planarization layer 106 is attached to the second surface of the color filter layer 102.

In the display substrate shown in FIG. 2, light directed to the color filter layer 102 may be white light. The white light is directed to the second surface of the color filter layer 102 after passing through the planarization layer 106, enters the color filter layer 102 at a larger light-emergent angle after being scattered by the scattering structure on the second surface, and then becomes colored light to be emitted from the base substrate 101, thereby realizing the color display of the display substrate 10.

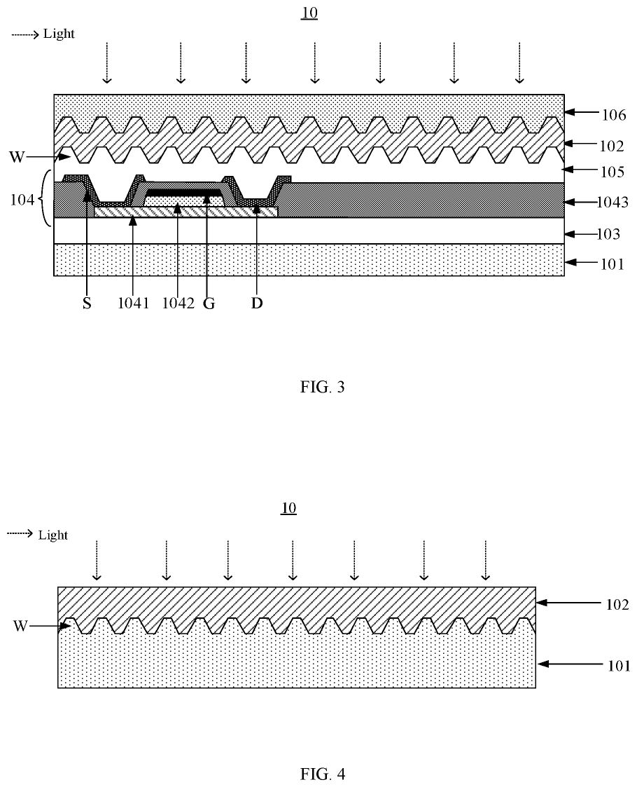

The structure of a third display substrate is shown in FIG. 3. FIG. 3 is a schematic structural diagram of another display substrate according to an embodiment of the present disclosure. As shown in FIG. 3, the scattering structure of the color filter layer 102 is provided both on the first surface and the second surface of the color filter layer 102. That is, the target surface of the color filter layer 102 includes the first surface and the second surface. The display substrate 10 further includes a passivation layer 105 located between the base substrate 101 and the color filter layer 102, and a planarization layer 106 located on a side, distal from the base substrate 101, of the color filter layer 102. The passivation layer 105 is attached to the first surface of the color filter layer 102. The planarization layer 106 is attached to the second surface of the color filter layer 102.

In the display substrate shown in FIG. 3, light directed to the planarization layer 106 may be white light. The white light is scattered upon being exited from the planarization layer 106. Then the scattered white light becomes colored light after entering the color filter layer 102. And the colored light is scattered again upon being exited from the color filter layer 102, and then is exited from the base substrate 101 at a larger light-emergent angle, thereby realizing the color display of the display substrate 10.

Optionally, in the display substrate shown in any of FIGS. 1 to 3, the color filter layer is made of an organic material, the passivation layer is made of at least one of silicon oxide, silicon nitride, and aluminum oxide, the planarization layer is made of photosensitive resin. That is, the material of the color filter layer is different from those of the passivation layer and the planarization layer, thereby improving the light scattering effect of the scattering structure on the target surface of the color filter layer.

Optionally, in the display substrate shown in any of FIGS. 1 to 3, the display substrate 10 includes a buffer layer 103, a thin-film transistor 104, and a passivation layer 105 disposed between the base substrate 101 and the color filter layer 102. The buffer layer 103, the thin-film transistor 104, and the passivation layer 105 are sequentially arranged in a direction distal from the base substrate 101. The buffer layer 103 is configured to block ions in the base substrate 101 diffusing to an active layer of the thin-film transistor 104, thereby preventing the diffused ions from affecting the performance of the thin-film transistor 104. The passivation layer 105 is configured to block the erosion of the thin-film transistor 104 by water and oxygen.

It should be noted that the thin-film transistor in the display substrate shown in any of FIGS. 1 to 3 is a top gate thin-film transistor or a bottom gate thin-film transistor. FIGS. 1 and 3 take the thin-film transistor 104 being a top gate thin-film transistor as an example for illustration. FIG. 2 illustrates the thin-film transistor 104 being a bottom gate thin-film transistor as an example. Referring to FIG. 1 or 3, the top gate thin-film transistor 104 includes an active layer pattern 1041, a gate insulating layer 1042, a gate G, an interlayer dielectric layer 1043, and a source/drain pattern laminated in a direction distal from the base substrate 101, and the source/drain pattern includes a source S and a drain D. Referring to FIG. 2, the bottom gate thin-film transistor 104 includes a gate G, a gate insulating layer 1042, an active layer pattern 1041, and a source/drain pattern laminated in a direction distal from the base substrate 101, and the source/drain pattern includes a source S and a drain D.

Optionally, the gate is made of one or more of aluminum (Al), neodymium (Nd), and molybdenum (Mo). The source/drain pattern is made of aluminum, neodymium and molybdenum. The active layer pattern is made of one or more of Indium Gallium Zinc Oxide (IGZO), Low Temperature Poly-silicon (LTPS) and Low Temperature Polycrystalline Oxide (LTPO).

Optionally, in the display substrate as shown in any of FIGS. 1 to 3, a self-luminous device is provided on a side, distal from the base substrate, of the color filter layer. The self-luminous device emits white light to a side where the color filter layer is located. After passing through the color filter layer, the white light is changed into colored light to be emitted, thereby realizing the color display of the display substrate.

Optionally, the self-luminous device is an OLED device. The OLED device includes an anode layer, a hole injection layer, a hole transport layer, an electroluminescent layer, an electron transport layer, an electron injection layer, and a cathode layer superimposed.

In another optional embodiment of the present disclosure, the above-mentioned display substrate is a color filter substrate. In an exemplary embodiment, FIG. 4 is a schematic structural diagram of still another display substrate according to an embodiment of the present disclosure. The color filter layer 102 is formed on the base substrate 101. Optionally, the color filter substrate further includes a black matrix. The color filter substrate is applicable to a liquid crystal display panel.

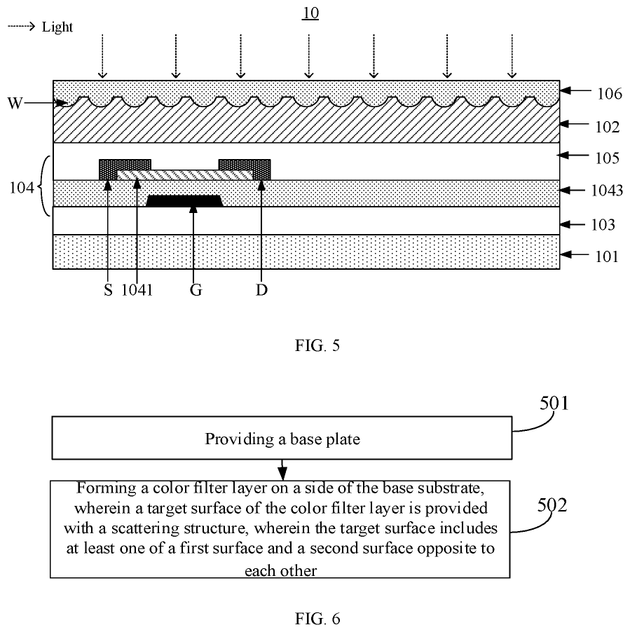

Optionally, in the display substrate as shown in any of FIGS. 1 to 4, the scattering structure of the target surface of the color filter layer 102 includes a plurality of grooves W. Optionally, the grooves are hemispherical-shaped, inverted triangular pyramid-shaped, or inverted prismatic table-shaped. That is, the plurality of grooves include at least one of hemispherical grooves, inverted triangular pyramid grooves, and inverted prismatic table grooves. Exemplarily, FIG. 5 shows a schematic structural diagram of another display substrate according to an embodiment of the present disclosure. In the display substrate, the scattering structure W of the target surface of the color filter layer 102 is hemispherical grooves.

In an exemplary embodiment, when the groove has a hemispherical shape, an aperture width of the groove refers to the diameter of the hemisphere. When the groove has an inverted triangular pyramid shape, the aperture width of the groove refers to a side length of a bottom surface of the inverted triangle. When the groove has an inverted prismatic table shape, the aperture width of the groove refers to an aperture width of a bottom surface of the inverted pyramid.

Optionally, the aperture widths of the grooves range from 50 to 700 nanometers. Since the closer the aperture width of the groove to the wavelength of light, the better the light scattering effect of the scattering structure, and the color filter layer usually includes one or more of a red filter area, a green filter area and a blue filter area. The wavelength of red light is 700 nanometers. The wavelength of green light is 546.1 nanometers. The wavelength of blue light is 435.8 nanometers. The display substrate is used to emit one or more of red light, green light and blue light. When the target surface of the color filter layer is provided with a scattering structure, and the aperture widths of the grooves in the scattering structure range from 50 to 700 nanometers, a better scattering effect can be achieved on one or more of red light, green light and blue light.

Optionally, the grooves in the scattering structure of the color filter layer may have the same or different opening dimension, which is not limited in the embodiment of the present disclosure. When the plurality of grooves in the scattering structure of the color filter layer have the same shape and the same opening dimension, the plurality of grooves are congruent. In this way, the manufacturing difficulty can be reduced, thereby improving manufacturing efficiency.

Optionally, the plurality of grooves is disposed in an array on the target surface of the color filter layer. That is, the plurality of grooves are uniformly arranged on the target surface of the color filter layer, which ensures that light directed to various positions on the target surface can be scattered uniformly, thereby ensuring the uniformity of light emitted by the display substrate. Optionally, the plurality of grooves is randomly distributed on the target surface of the color filter layer.

It should be noted that since the target surface of the color filter layer is provided with the scattering structure, the scattering structure includes grooves, and the first film layer is attached to the target surface, the color filter layer and the first film layer are firmly attached, which reduces the risk of the color filter layer falling off and improves the yield of the display substrate.

In the embodiments of the present disclosure, the scattering structure is directly formed on the target surface of the color filter layer, without preparing separately by other materials. Therefore, the material usage and process steps can be reduced, thereby reducing the preparation cost of the display substrate, and making the display substrate lighter and thinner.

In summary, according to the display substrate provided by the embodiment of the present disclosure, since the target surface of the color filter layer is provided with the scattering structure which plays a role in scattering light, the light can be scattered upon being exited from the scattering structure. In this way, the light-emergent angle of the display substrate is larger, which enables a display panel including the display substrate to have a larger viewing angle.

FIG. 6 is a flowchart of a method for manufacturing a display substrate according to an embodiment of the present disclosure. The method is used to manufacture the display substrate shown in any of FIGS. 1 to 5. As shown in FIG. 6, the method includes the following steps.

In 501, a base substrate is provided.

In 502, a color filter layer is formed on a side of the base substrate, wherein a target surface of the color filter layer is provided with a scattering structure, and the target surface includes at least one of a first surface and a second surface opposite to each other.

In summary, according to the display substrate prepared by the method provided by the embodiment of the present disclosure, since the target surface of the color filter layer is provided with the scattering structure which plays a role in scattering light, the light can be scattered upon being exited from the scattering structure. In this way, the light-emergent angle of the display substrate is larger, which enables a display panel including the display substrate to have a larger viewing angle.

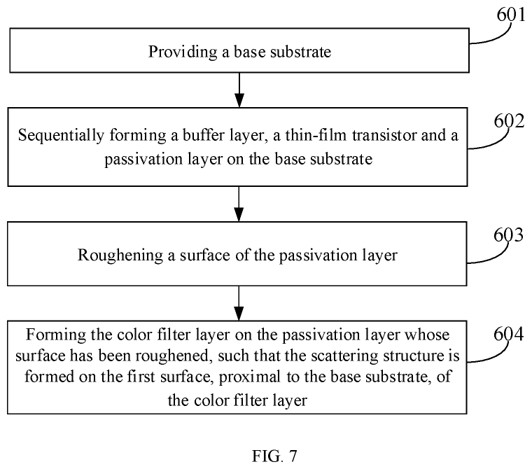

FIG. 7 is a flowchart of another method for manufacturing a display substrate according to an embodiment of the present disclosure. The method is used to manufacture the display substrate shown in FIG. 1. As shown in FIG. 7, the method includes the following steps.

In 601, a base substrate is provided.

Optionally, the base substrate is made of one or more of glass, quartz and plastic, which is not limited in the embodiment of the present disclosure.

In 602, a buffer layer, a thin-film transistor, and a passivation layer are sequentially formed on the base substrate.

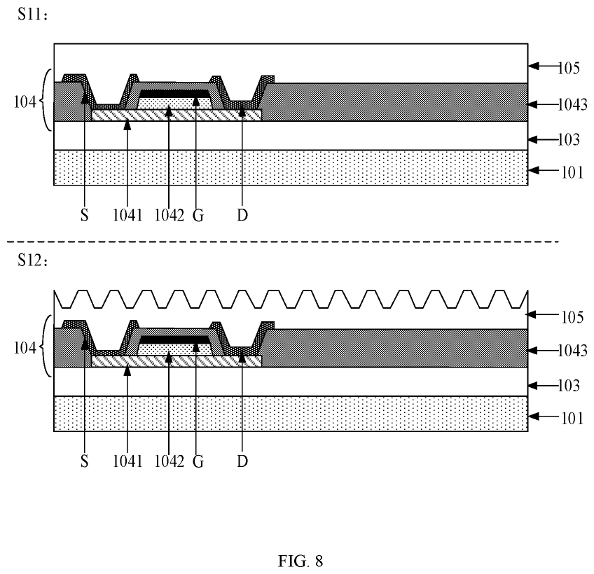

In an exemplary embodiment, referring to S11 in FIG. 8, a buffer layer 103, a thin-film transistor 104, and a passivation layer 105 is sequentially formed on the base substrate 101.

In an optional embodiment of the present disclosure, when the thin-film transistor is a top gate thin-film transistor, the forming the thin-film transistor on the base substrate on which the buffer layer has been formed includes the following steps.

In 61a, an active layer pattern is formed on the base substrate on which the buffer layer has been formed.

Optionally, the active layer pattern is made of at least one of IGZO, LTPS, and LTPO. For example, the active layer pattern is formed on the base substrate by a patterning process. The patterning process include photoresist coating, exposure, development, etching and photoresist stripping.

In 62a, a gate insulating layer is formed on the base substrate on which the active layer pattern has been formed.

Optionally, the gate insulating layer is made of at least one of silicon dioxide, silicon nitride, and aluminum oxide. For example, the gate insulating layer is formed by deposition on the base substrate on which the active layer pattern has been formed.

In 63a, a gate is formed on the base substrate on which the gate insulating layer has been formed.

Optionally, the gate is made of at least one of aluminum, neodymium, and molybdenum. For example, the gate is formed, by a patterning process, on the base substrate on which the gate insulating layer has been formed.

In 64a, an interlayer dielectric layer is formed on the base substrate on which the gate has been formed.

Optionally, the interlayer dielectric layer is made of at least one of silicon dioxide, silicon nitride, and aluminum oxide. For example, the interlayer dielectric layer is formed by deposition on the base substrate on which the gate has been formed.

In 65a, a source/drain pattern is formed on the base substrate on which the interlayer dielectric layer has been formed.

Optionally, the source/drain pattern is made of at least one of aluminum, neodymium, and molybdenum. For example, the source/drain pattern is formed, by a patterning process, on the base substrate on which the passivation layer has been formed.

In another optional embodiment of the present disclosure, when the thin-film transistor is a bottom gate thin-film transistor, the forming the thin-film transistor on the base substrate on which the buffer layer has been formed includes the following steps.

In 61b, a gate is formed on the base substrate where the buffer layer has been formed.

For a material and preparation method of the gate, reference may be made to the above step 63a, which are not repeated in the embodiment of the present disclosure.

In 62b, a gate insulating layer is formed on the base substrate on which the gate has been formed.

For a material and preparation method of the gate insulating layer, reference may be made to the above step 62a, which are not repeated in the embodiment of the present disclosure.

In 63b, an active layer pattern is formed on the base substrate on which the gate insulating layer has been formed.

For a material and preparation method of the active layer pattern, reference may be made to the above step 61a, which are not repeated in the embodiment of the present disclosure.

In 64b, a source/drain pattern is formed on the base substrate on which the active layer pattern has been formed.

For a material and preparation method of the source/drain pattern, reference may be made to the above step 65a, which are not repeated in the embodiment of the present disclosure.

In 603, a surface of the passivation layer is roughened.

In an exemplary embodiment, referring to S12 in FIG. 8, the surface of the passivation layer 105 is roughened to be uneven, that is, to make the surface be provided with a plurality of grooves and protrusions.

Optionally, in some embodiments, the surface of the passivation layer is sprayed by a solution capable of chemically reacting with the passivation layer, so as to corrode the passivation layer to make the surface uneven, and the passivation layer is wished after a specified period of time, thereby realizing roughening treatment on the surface of the passivation layer. Optionally, in this case, the plurality of grooves and the plurality of protrusions on the surface of the passivation layer are randomly distributed, and the plurality of grooves may also have different dimensions.

In an exemplary embodiment, the passivation layer is made of silicon oxide, the solution capable of chemically reacting with the passivation layer is hydrofluoric acid, and the specified period of time is in the range of 100 seconds to 300 seconds. For example, a hydrofluoric acid solution with a concentration range of 0.5% to 2% is used to spray the surface of the passivation layer, and the passivation layer is wished after the hydrofluoric acid solution reacts with the passivation layer for 100 to 300 seconds.

Optionally, in some embodiments, the surface of the passivation layer is etched to be uneven, thereby achieving roughening treatment on the surface of the passivation layer. Optionally, in this case, the plurality of grooves and the plurality of protrusions on the surface of the passivation layer is disposed in an array (for example, uniformly arranged), and the plurality of grooves have the same dimension.

In 604, a color filter layer is formed on the passivation layer whose surface has been roughened, so as to form the scattering structure on the first surface, proximal to the base substrate, of the color filter layer.

In an exemplary embodiment, referring to FIG. 1, the color filter layer 102 is formed on the passivation layer 105 whose surface is uneven. Optionally, the color filter layer 102 includes one or more of a red filter area, a green filter area, and a blue filter area.

Since the surface of the passivation layer 105 is uneven, after the color filter layer 102 is formed on the uneven surface, the surface of the color filter layer 102 which is attached to the passivation layer 105 is also uneven. The protrusions on the surface of the passivation layer 105 correspond to the grooves on the surface of the color filter layer 102, and grooves on the surface of the passivation layer 105 correspond to the protrusions on the surface of the color filter layer 102. Furthermore, the surface of the color filter layer 102 which is attached to the passivation layer 105 (that is, the first surface of the color filter layer 102 proximal to the base substrate) is provided with a scattering structure. The scattering structure includes a plurality of grooves. If the plurality of protrusions on the surface of the passivation layer 105 are randomly distributed, the plurality of grooves on the surface of the color filter layer 102 which is attached to the passivation layer 105 are also randomly distributed. Correspondingly, if the plurality of protrusions on the surface of the passivation layer 105 are uniformly arranged, the plurality of grooves on the surface of the color filter layer 102 which is attached to the passivation layer 105 are also uniformly arranged.

Optionally, after the color filter layer has been formed, a self-luminous device is formed on a side, distal from the base substrate, of the color filter layer. The self-luminous device emits light toward a side where the color filter layer is located. Then, the surface of the color filter layer which is provided with a scattering structure is a light-emergent surface of the color filter layer. Optionally, the self-luminous device is an OLED. The self-luminous device is an anode layer, a hole injection layer, a hole transport layer, an electroluminescence layer, an electron transport layer, an electron injection layer, and a cathode layer laminated in sequence.

In summary, according to the display substrate prepared by the method provided by the embodiment of the present disclosure, since the target surface of the color filter layer is provided with the scattering structure which plays a role in scattering light, the light can be scattered upon being exited from the scattering structure. In this way, the light-emergent angle of the display substrate is larger, which enables a display panel including the display substrate to have a larger viewing angle.

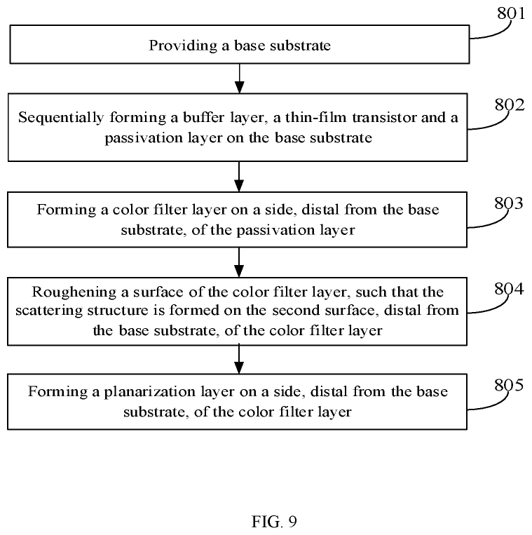

FIG. 9 is a flowchart of another method for manufacturing a display substrate according to an embodiment of the present disclosure. The method is applicable to manufacture the display substrate shown in FIG. 2. As shown in FIG. 9, the method includes the following steps.

In 801, a base substrate is provided.

For step 801, reference may be made to step 601, which is not repeated in the embodiment of the present disclosure.

In 802, a buffer layer, a thin-film transistor and a passivation layer are sequentially formed on the base substrate.

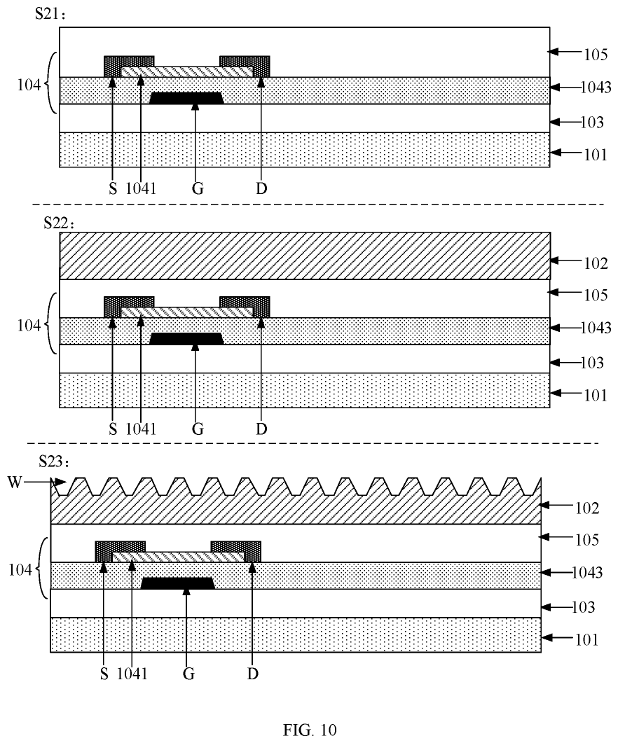

In an exemplary embodiment, referring to S21 in FIG. 10, a buffer layer 103, a thin-film transistor 104, and a passivation layer 105 are sequentially formed on the base substrate 101. It should be noted that for step 802, reference may be made to step 602, which is not repeated in the embodiment of the present disclosure.

In 803, a color filter layer is formed on a side, distal from the base substrate, of the passivation layer.

In an exemplary embodiment, referring to S22 in FIG. 10, a color filter layer 102 is formed on the passivation layer 105. Optionally, the color filter layer 102 includes one or more of a red filter area, a green filter area, and a blue filter area.

In 804, a surface of the color filter layer is roughened to form a scattering structure on the second surface, distal from the base substrate, of the color filter layer.

In an exemplary embodiment, referring to S23 in FIG. 10, the surface of the color filter layer 102 is roughened to be uneven, that is, to make the surface be provided with a scattering structure. The scattering structure includes a plurality of grooves W randomly distributed or uniformly arranged.

Optionally, the color filter layer 102 is made of an organic material. The plurality of grooves are formed on the surface of the color filter layer 102 by nano-imprinting.

In 805, a planarization layer is formed on a side, distal from the base substrate, of the color filter layer.

In an exemplary embodiment, referring to S24 in FIG. 10, a planarization layer 106 is formed on the color filter layer 102 whose surface has been roughened. Optionally, the planarization layer 102 is made of a resin material.

Optionally, after the planarization layer has been formed, a self-luminous device is formed on a side, distal from the base substrate, of the planarization layer. The self-luminous device emits light toward a side where the color filter layer is located. Then, the surface of the color filter layer which is provided with a scattering structure is a light-incident surface of the color filter layer. For the description of the self-luminous device, reference may be made to step 604, which is not repeated in the embodiment of the present disclosure.

In summary, according to the display substrate prepared by the method provided by the embodiments of the present disclosure, since the target surface of the color filter layer is provided with the scattering structure which plays a role in scattering light, the light can be scattered upon being exited from the scattering structure. In this way, the light-emergent angle of the display substrate is larger, which enables a display panel including the display substrate to have a larger viewing angle.

Optionally, in the embodiment of the present disclosure, steps 601 to 604 in FIG. 7 are performed, and then steps 804 and 805 in FIG. 9 are performed, so as to obtain the display substrate 10 as shown in FIG. 3. For the manufacturing process of the display substrate shown in FIG. 3, reference may be made to the introduction of steps 601 to 604, and steps 804 and 805, which is not repeated in the embodiment of the present disclosure.

An embodiment of the present disclosure also provides a display panel, which may include the display substrate shown in any of FIGS. 1 to 5.

When the display panel includes the display substrate shown in any of FIGS. 1 to 3, the display panel may further include a cover plate disposed on a side, distal from the base substrate, of the color filter layer.

When the display panel includes the display substrate 10 shown in FIG. 4 (that is, a color filter substrate), the display panel may be a liquid crystal display panel or a self-luminous display panel.

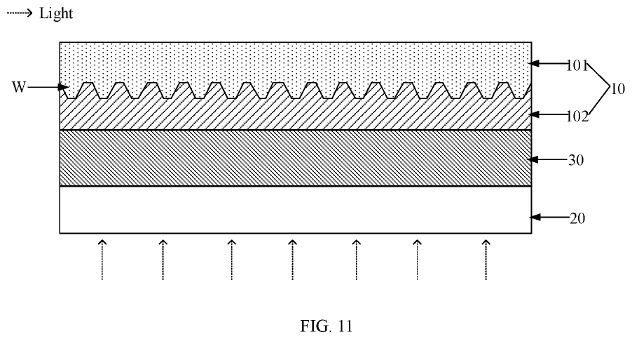

In an exemplary embodiment, when the display panel is a liquid crystal display panel, as shown in FIG. 11, the liquid crystal display panel includes an array substrate 20 which is aligned with the display substrate 10, and a liquid crystal layer 30 located between the display substrate 10 and the array substrate 20. A backlight module may also be provided on a side, distal from the display substrate 10, of the array substrate 20. The backlight module emits light toward a side where the display substrate 10 is located.

In another exemplary embodiment, when the display panel is a self-luminous display panel, the display panel may include an array substrate which is aligned with the color filter substrate, and a self-luminous device located between the color filter substrate and the array substrate. The self-luminous device emits light toward a side where the color filter substrate is located. Optionally, the self-luminous device is an OLED device or a QLED device.

An embodiment of the present disclosure also provides a display device, which includes the above-mentioned display panel. In some embodiments, the display device according to the embodiment of the present disclosure is any product or component with a display function, such as a mobile phone, a tablet computer, a television, a monitor, a notebook computer, a digital photo frame, a navigator, and the like.

It should be noted that the manufacturing method embodiments according to the embodiments of the present disclosure are cross-referenced with the corresponding display substrate embodiments, which is not limited in the embodiments of the present disclosure. The sequence of the steps in the method embodiments according to the embodiments of the present disclosure may be adjusted appropriately, and the steps may be increased or decreased as required. All variants that those skilled in the art can easily think of within the technical scope disclosed in the present disclosure should be covered by the scope of protection of the present disclosure, and will not be repeated here.

It should be noted that in the drawings, the dimensions of layers and regions may be exaggerated for clarity of illustration. It should also be understood that when an element or layer is referred to as being “on” another element or layer, it can be directly on another element or an intervening layer may be present. In addition, it should be understood that when an element or layer is referred to as being “below” another element or layer, it can be directly below another element, or more than one intervening layer or element may be present. In addition, it should also be understood that when a layer or element is referred to as being “between” two layers or two elements, it can be the only layer between the two layers or elements, or more than one intervening layer or element may also be present. Similar reference numerals indicate similar elements throughout.

In the embodiments of the present disclosure, the terms “first” and “second” are only used for descriptive purposes, and shall not be understood as indicating or implying relative importance. The term “a plurality of” refers to two or more, unless specifically defined otherwise. The “at least one” mentioned in the embodiments of the present disclosure all mean “one or more”.

Described above are merely optional embodiments of the present disclosure, but are not intended to limit the present disclosure. Any modifications, equivalent replacements, improvements and the like made within the spirit and principles of the present disclosure should be included within the scope of protection of the present disclosure.

1. A display substrate, comprising:
a base substrate and a color filter layer disposed on a side of the base substrate, wherein a target surface of the color filter layer is provided with a scattering structure, and the target surface comprises at least one of a first surface and a second surface opposite to each other.

2. The display substrate according to claim 1, wherein the scattering structure comprises a plurality of grooves.

3. The display substrate according to claim 2, wherein the plurality of grooves comprise at least one of hemispherical grooves, inverted triangular pyramid grooves, and inverted prismatic table grooves.

4. The display substrate according to claim 2, wherein the plurality of grooves are uniformly arranged on the target surface.

5. The display substrate according to claim 2, wherein opening dimensions of the plurality of grooves are the same.

6. The display substrate according to claim 2, wherein aperture widths of the grooves range from 50 to 700 nanometers.

7. The display substrate according to claim 1, further comprising a first film layer attached to the target surface, wherein a material of the first film layer is different from a material of the color filter layer.

8. The display substrate according to claim 7, wherein the target surface comprises the first surface proximal to the base substrate, the first film layer comprises a passivation layer, and the display substrate comprises a buffer layer and a thin-film transistor between the base substrate and the color filter layer, wherein the buffer layer, the thin-film transistor, and the passivation layer are sequentially arranged in a direction distal from the base substrate.

9. The display substrate according to claim 7, wherein the target surface comprises the second surface distal from the base substrate, the first film layer comprises a planarization layer, and the display substrate comprises a buffer layer and a thin-film transistor between the base substrate and the color filter layer, wherein the buffer layer, the thin-film transistor, the passivation layer, the color filter layer and the planarization layer are sequentially arranged in a direction distal from the base substrate.

10. The display substrate according to claim 9, wherein the color filter layer is made of an organic material, the passivation layer is made of at least one of silicon oxide, silicon nitride, and aluminum oxide, and the planarization layer is made of photosensitive resin.

11. The display substrate according to claim 3, wherein shapes of the plurality of grooves are the same.

12. The display substrate according to claim 1, wherein the scattering structure comprises a plurality of grooves;
the plurality of grooves comprise any of hemispherical grooves, inverted triangular pyramid grooves, or inverted prismatic table grooves, and opening dimensions of the plurality of grooves are the same;
the plurality of grooves are uniformly arranged on the target surface;
the display substrate comprises a first film layer attached to the target surface, wherein a material of the first film layer is different from a material of the color filter layer; and
the target surface comprises the first surface proximal to the base substrate, the first film layer comprises a passivation layer, and the display substrate comprises a buffer layer and a thin-film transistor between the base substrate and the color filter layer, wherein the buffer layer, the thin-film transistor and the passivation layer are sequentially arranged in a direction distal from the base substrate.

13. A method for manufacturing a display substrate, comprising:
providing a base substrate;
forming a color filter layer on a side of the base substrate, wherein a target surface of the color filter layer is provided with a scattering structure, and the target surface comprises at least one of a first surface and a second surface opposite to each other.

14. The method according to claim 13, wherein after providing the base substrate, the method further comprises:
sequentially forming a buffer layer, a thin-film transistor, and a passivation layer on the base substrate; and
roughening a surface of the passivation layer; and
forming the color filter layer on a side of the base substrate comprises:
forming the color filter layer on the passivation layer with the surface roughened, such that the scattering structure is formed on the first surface, proximal to the base substrate, of the color filter layer.

15. The method according to claim 13, wherein after providing the base substrate, the method further comprises:
sequentially forming a buffer layer, a thin-film transistor, and a passivation layer on the base substrate; and
forming the color filter layer on one side of the base substrate comprises:
forming the color filter layer on a side, distal from the base substrate, of the passivation layer; and
roughening a surface of the color filter layer, such that the scattering structure is formed on the second surface, distal from the base substrate, of the color filter layer.

16. The method according to claim 15, wherein after forming the color filter layer on one side of the base substrate, the method further comprises:
forming a planarization layer on a side, distal from the base substrate, of the color filter layer.

17. The method according to claim 13, wherein the scattering structure comprises a plurality of grooves.

18. The method according to claim 17, wherein the plurality of grooves comprise at least one of hemispherical grooves, inverted triangular pyramid grooves, and inverted prismatic table grooves.

19. The method of claim 17, wherein the plurality of grooves are uniformly arranged on the target surface, and aperture widths of the grooves range from 50 to 700 nanometers.

20. A display panel comprising a display substrate, wherein the display substrate comprises a base substrate and a color filter layer disposed on a side of the base substrate, wherein a target surface of the color filter layer is provided with a scattering structure, and the target surface comprises at least one of a first surface and a second surface opposite to each other.
